(19) United States
(12) Patent Application Publication
(10) Pub. No.: US 2024/0213045 A1
(43) Pub. Date: Jun. 27, 2024

(54) SUBSTRATE CLEANING APPARATUS AND SUBSTRATE CLEANING METHOD

(71) Applicant: EBARA CORPORATION, Tokyo (JP)

(72) Inventor: Tomoatsu ISHIBASHI, Tokyo (JP)

(21) Appl. No.: 18/394,735

(22) Filed: Dec. 22, 2023

(30) Foreign Application Priority Data
Dec. 26, 2022 (JP) 2022-208562

(51) Int. Cl. H01L 21/67; B08B 1/12; B08B 1/20; B08B 1/34; B08B 1/36; B08B 3/04; B08B 3/08

(52) U.S. Cl. CPC H01L 21/67046; B08B 1/12; B08B 1/20; B08B 1/34; B08B 1/36; B08B 3/041; B08B 3/08; H01L 21/67051

(57) ABSTRACT

A substrate cleaning apparatus according to the present invention comprises a cleaning member that contacts with a substrate to clean the substrate; and a supply mechanism that provides an organic solvent for dissolution to the substrate after the substrate is cleaned by the cleaning member. The organic solvent for dissolution can dissolve a foreign substance generation factor caused by the cleaning member.

### CROSS-REFERENCE TO RELATED APPLICATION

The present application claims the priority of Japanese Patent Application No. 2022-208562 filed on Dec. 26, 2022, the contents of which are entirely incorporated by reference.

### TECHNICAL FIELD

The present invention relates to a substrate cleaning apparatus and a substrate cleaning method used for cleaning a substrate such as a semiconductor wafer.

### BACKGROUND ART

Along with miniaturization of semiconductor devices in recent years, various material films having different physical properties are formed on a substrate and processed. In particular, in a damascene wiring forming step of filling a wiring groove formed in a substrate with metal, excess metal is polished and removed by a substrate polishing apparatus (CMP) after the damascene wiring is formed, but films having different wettability to water, such as a metal film, a barrier film, and an insulating film, exist on a substrate surface. On surfaces of these, slurry residues and polishing wastes of a polishing agent used by CMP polishing are present. If the substrate surface is not sufficiently cleaned, leakage may occur from the portion due to a residue or the like, and there may be a problem in terms of reliability such as a cause of poor adhesion.

By cleaning the substrate with a roll cleaning member, the slurry residues of the polishing agent and the polishing wastes are removed, but foreign substances caused by the roll cleaning member may adhere to the substrate. In this regard, for example, by using a pencil cleaning member as disclosed in JP 2016-092158 A, generation of foreign substances caused by the roll cleaning member can be suppressed to some extent.

### SUMMARY OF INVENTION

### Problem to be Solved by Invention

However, with the miniaturization of semiconductor devices in recent years, the demand for a degree of cleaning in substrate processing apparatuses such as cleaning apparatuses has further increased, and it has been required to suppress contamination caused by cleaning members with higher accuracy.

The present invention has been made in view of such a point, and provides a substrate cleaning apparatus and a substrate cleaning method capable of suppressing contamination caused by a cleaning member with higher accuracy.

### Means for Solving Problem

### [Concept 1]

A substrate cleaning apparatus according to the present invention may comprise:
a cleaning member that contacts with a substrate to clean the substrate; and
a supply mechanism that provides an organic solvent for dissolution to the substrate after the substrate is cleaned by the cleaning member, the organic solvent for dissolution being to dissolve a foreign substance generation factor caused by the cleaning member.

### [Concept 2]

In the substrate cleaning apparatus according to concept 1,
the organic solvent for dissolution may include a liquid isopropyl alcohol.

### [Concept 3]

In the substrate cleaning apparatus according to concept 1 or 2,
the supply mechanism may have an ejection part that ejects the organic solvent for dissolution to the substrate.

### [Concept 4]

In the substrate cleaning apparatus according to concept 3,
the ejection part may be electrically connected to a ground.

### [Concept 5]

In the substrate cleaning apparatus according to any one of concepts 1 to 4,
the supply mechanism may have an immersion part for immersing the substrate in the organic solvent for dissolution.

### [Concept 6]

The substrate cleaning apparatus according to any one of concepts 1 to 5 may further comprise a dedicated cleaning member that contacts with the substrate to clean the substrate, while the organic solvent for dissolution is provided to the substrate.

### [Concept 7]

In the substrate cleaning apparatus according to any one of concepts 1 to 6, the cleaning member may include a roll cleaning member and a pencil cleaning member, the supply mechanism may provide the organic solvent for dissolution to the substrate, after the substrate is cleaned by the roll cleaning member and the pencil cleaning member.

### [Concept 8]

The substrate cleaning apparatus according to any one of concepts 1 to 7 may further comprise a rotation part that rotates the substrate,
a rotation of the substrate may be slower than the rotation of the substrate at a time of cleaning the substrate with a chemical liquid or a rinse liquid, or the rotation of the substrate may be stopped, while the organic solvent for dissolution is provided by the supply mechanism.

### [Concept 9]

In the substrate cleaning apparatus according to any one of concepts 1 to 8, a temperature of the organic solvent for dissolution may be 30° C. or more and 60° C. or less.

### [Concept 7]

A substrate cleaning method according to the present invention may comprise:
a step of bringing a cleaning member into contact with a substrate to clean the substrate; and
a step of providing, by a supply mechanism, an organic solvent for dissolution to the substrate after the substrate is cleaned by the cleaning member, the organic solvent for dissolution being to dissolve a foreign substance generation factor caused by the cleaning member.

### Effect of Invention

As one of aspects of the invention, an aspect in which an organic solvent for dissolution to the substrate is provided to the substrate after the substrate is cleaned by the cleaning member, the organic solvent for dissolution being to dissolve a foreign substance generation factor caused by the cleaning member, it is possible to suppress contamination caused by a cleaning member with higher accuracy.

### BRIEF DESCRIPTION OF DRAWINGS

FIG. 1 is an upper plan view showing an overall configuration of a substrate processing apparatus including a substrate cleaning apparatus according to an embodiment of the present invention;

FIG. 2 is a perspective view showing a configuration of a roll cleaning member that can be used in the embodiment of the present invention;

FIG. 3 is a side view showing a configuration of a pencil cleaning member that can be used in the embodiment of the present invention;

FIG. 4 is a flowchart showing one example of a processing process that can be used in the embodiment of the present invention;

FIG. 5 is a side view showing one example of an aspect using an ejection part that can be used in the embodiment of the present invention;

FIG. 6 is a side view showing one example of an aspect using an immersion part that can be used in the embodiment of the present invention;

FIG. 7 is a side view showing another example of the aspect using the immersion part that can be used in the embodiment of the present invention (a first modification of the aspect using the immersion part);

FIG. 8 is a side view showing another example of the aspect using the ejection part that can be used in the embodiment of the present invention (a first modification of the aspect using the ejection part);

FIG. 9 is a side view showing still another example of the aspect using the ejection part that can be used in the embodiment of the present invention (a second modification of the aspect using the ejection part);

FIG. 10 is a side view showing still another example of the aspect using the immersion part that can be used in the embodiment of the present invention (a second modification of the aspect using the immersion part);

FIG. 11 is a side view showing one example of an aspect using a dedicated cleaning member that can be used in the embodiment of the present invention (the aspect using the ejection part);

FIG. 12 is a side view showing another example of the aspect using the dedicated cleaning member that can be used in the embodiment of the present invention (the aspect using the immersion part); and

FIG. 13 is a photograph showing measurement results using AFM and TOF-SIMS.

### DETAILED DESCRIPTION

### Description of Embodiments

An embodiment of a substrate processing apparatus having a substrate cleaning apparatus according to the present invention will be described with reference to the figures.

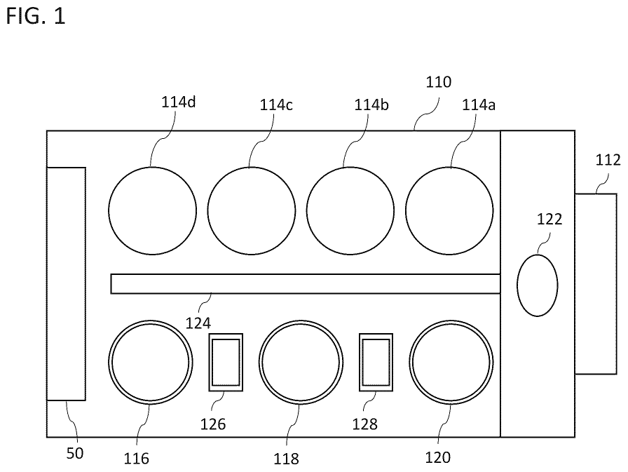

As shown in FIG. 1, the substrate processing apparatus has a housing 110 that is substantially rectangular in a plane view, and a load port 112; a substrate cassette that stocks a number of substrates W is put on the load port 112. The load port 112 is placed adjacent to the housing 110. The load port 112 can be loaded with an open cassette, a SMIF (Standard Mechanical Interface) pod or a FOUP (Front Opening Unified Pod). A SMIF pod and a FOUP are hermetically sealed enclosure that stores therein a substrate cassette and covers it with a bulkhead, and whereby an environment independent of the external space can be maintained. The substrate W is, for example, a semiconductor wafer and the like.

Inside the housing 110, a plurality of (in an aspect shown in FIG. 1, four) polishing units 114a to 114d, first and second cleaning units 116 and 118 for cleaning a polished substrate W, and a drying unit 120 for drying the cleaned substrate W is contained. The polishing units 114a to 114d are arranged along a long side of the substrate processing apparatus, and the cleaning units 116 and 118 and the drying unit 120 are also arranged along the long side of the substrate processing apparatus.

In an area surrounded by the load port 112, and the polishing unit 114a and the drying unit 120 that are located on the side of the load port 112, a first transfer robot 122 is placed. Furthermore, a conveyance unit 124 is placed parallel to the polishing units 114a to 114d as well as the cleaning units 116 and 118 and the drying unit 120. The first transfer robot 122 receives a pre-polished substrate W from the load port 112 and transfers the substrate W to the conveyance unit 124, or receives a dried substrate W, which is taken out from the drying unit 120, from the conveyance unit 124.

A second transfer robot 126 for transferring a substrate W between the first cleaning unit 116 and the second cleaning unit 118 is placed between the first cleaning unit 116 and the second cleaning unit 118, and a third conveyance robot 128 for transferring the substrate W between the second cleaning unit 118 and the drying unit 120 is placed between the second cleaning unit 118 and the drying unit 120. Furthermore, inside the housing 110, a control part 50 for controlling the operation of each device of the substrate processing apparatus is placed. In the present embodiment, there is described the aspect in which the control part 50 is placed inside the housing 110; however, the placement of the control part 50 is not limited to this, and the control part 50 may be placed outside the housing 110, and the control part 50 may allow remote operation from a remote place. The control part 50 may consist of a plurality of devices, and when the control part 50 consists of multiple devices, the devices constituting the control part 50 may be located in different rooms or different locations, and a part of the control part 50 and the remainder of the control part 50 may be located at a remote location.

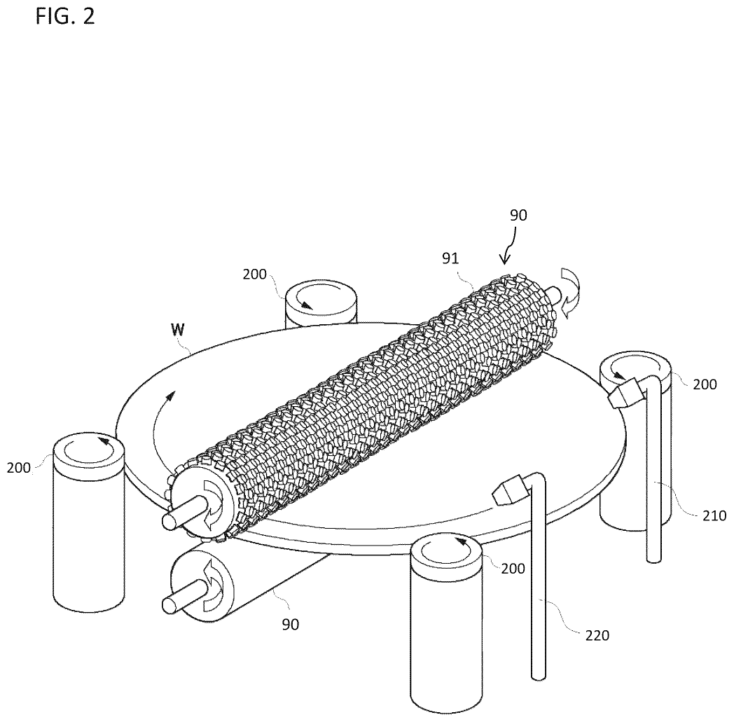

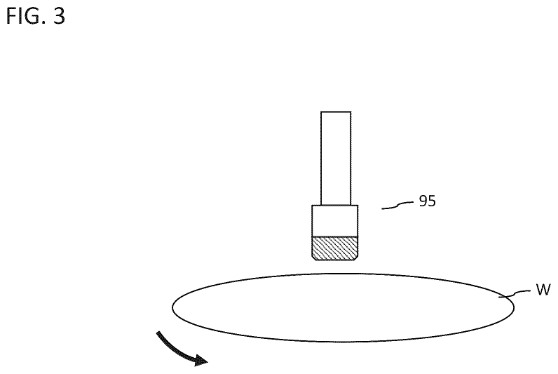

A roll cleaning apparatus for scrubbing a surface of a substrate W while rotating around the center axis parallel with the substrate W by bringing the roll cleaning member 90 linearly extending almost along the full diameter of the substrate W into contact with cleaning liquid may be used for the first cleaning unit 116 (see FIG. 2). A pencil cleaning apparatus for scrubbing a surface of a substrate W by bringing the lower end contact face of the vertically-extending columnar pencil cleaning member 95 into contact with cleaning liquid and moving the pencil cleaning member 95 in one direction while rotating may be used for the second cleaning unit 118 (see FIG. 3). A spin drying unit for drying a substrate W by injecting IPA steam from a moving injection nozzle toward the horizontally-held and rotating substrate W and drying the substrate W by centrifugal force by faster rotating the substrate W may be used for the drying unit 120.

The first cleaning unit 116 may use not a roll cleaning apparatus, but a pencil cleaning apparatus similar to the second cleaning unit 118 or a two-fluid jet cleaning apparatus for cleaning a surface of a substrate W by two-fluid jet. Further, the second cleaning unit 118 may use not a pencil cleaning apparatus, but a roll cleaning apparatus similar to the first cleaning unit 116, or a two-fluid jet cleaning apparatus for cleaning a surface of a substrate W by two-fluid jet. An aspect of the present invention can be applied to both the first cleaning unit 116 and the second cleaning unit 118, and can also be used with a roll cleaning apparatus, a pencil cleaning apparatus, an ultrasonic cleaning apparatus, and/or a two-fluid jet cleaning apparatus.

The cleaning liquid in the present embodiment contains rinse liquid, such as deionized water (DIW) and ultra pure water (UPW), and chemical liquid, such as ammonia hydrogen peroxide (SC1), hydrochloric acid hydrogen peroxide (SC2), sulfuric acid hydrogen peroxide (SPM), sulfuric acid hydrolysate, or hydrofluoric acid. In the present embodiment, unless otherwise specified, cleaning liquid means either rinse liquid or chemical liquid.

A substrate cleaning apparatus of the present embodiment may have a support part that supports the substrate W, a rotation part that rotates the substrate W supported by the support part, cleaning liquid supply parts 210, 220 (see FIG. 2) that supply the cleaning liquid to the substrate W, cleaning members 90, 95 that come into contact with the substrate W to clean the substrate W, and an IPA supply mechanism (supply mechanism) that provides isopropyl alcohol (IPA) as liquid to the substrate W cleaned by the cleaning members 90, 95. In the present application, “isopropyl alcohol” is also referred to as “IPA”. In the present embodiment, an aspect in which liquid IPA (hereinafter, the liquid is referred to as “liquid IPA”.) is supplied to the substrate W is described as an example of an organic solvent for dissolution, but the organic solvent for dissolution is not limited thereto, and methanol, ethanol, halogen-containing organic solvents, sulfur-containing organic solvents, nitrogen-containing organic solvents, hydrocarbon-based solvents, and the like can also be used as the organic solvent for dissolution. However, the use of the liquid IPA is advantageous in that a price of IPA itself is low and the liquid IPA is an organic solvent that is relatively easy to supply IPA in a semiconductor manufacturing factory. That is, when an organic solvent other than IPA is adopted, it is necessary to separately prepare a supply facility on a factory side, but when IPA made of steam is already used for drying the substrate W, it is advantageous in that the liquid IPA can be supplied using an identical supply source to a supply source of IPA made of steam, and an effect according to the present embodiment can be realized at a low introduction cost. The liquid IPA is preferably 100% as the organic solvent, but is not limited thereto, and an aspect in which the liquid IPA is contained in an amount of more than 50% as the organic solvent may be adopted. In this case, for example, a mixture of the liquid IPA and water may be provided as an organic solvent.

The support part may support the substrate W so that the substrate W extends in a horizontal direction, may hold the substrate W so that the substrate W extends in a vertical direction, or may hold the substrate W so that the substrate W is inclined from the horizontal direction. The support part may rotate while chucking or sucking and holding the substrate W, or may support the substrate W while rotating the substrate W like spindles 200 shown in FIG. 2. In the case of adopting the spindles 200, since the spindles 200 rotate while supporting the substrate W, the spindles 200 also function as both the support part and the rotation part, and the spindles 200 function as a rotation support part. In the present embodiment, “support” is a concept including “holding”, and for example, “holding” by a chuck is included in “support”.

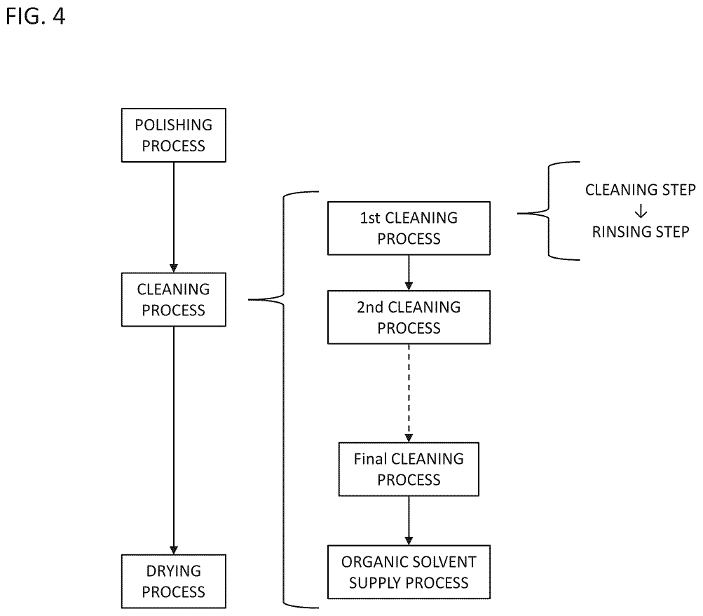

In the substrate cleaning apparatus such as a CMP, as shown in FIG. 4, a cleaning process is performed after a polishing process, and then a drying process is performed. The IPA supply mechanism of the present embodiment provides the liquid IPA to the substrate W, for example, in the cleaning process between the polishing process and the drying process. In the cleaning process, it is assumed that polishing wastes and a polishing agent on the surface of the substrate W are removed. Note that, as a result of contact with another cleaning liquid or the like, there is a possibility that a foreign substance generation factor is altered, and thus it is very beneficial to provide the liquid IPA to the substrate W immediately after cleaning by physical contact by the cleaning members 90, 95. In this case, in the cleaning process in FIG. 4, the liquid IPA is provided to the substrate W immediately after the cleaning of the substrate W by the physical contact by the cleaning members 90, 95 is finished.

The cleaning process may be performed once, but a plurality of cleaning processes may be performed as shown in FIG. 4 (the cleaning process may be performed in multiple stages). When the plurality of cleaning processes are performed, a cleaning step including physical cleaning and/or liquid cleaning, and a rinsing step with pure water or chemical liquid may be performed in each of the cleaning processes. The physical cleaning is a concept including contact cleaning and non-contact cleaning. In the contact cleaning, cleaning using the roll cleaning members 90 and/or the pencil cleaning members 95 and chemical liquid or pure water may be performed, or buff cleaning (buff polishing) may be performed. In the non-contact cleaning, ultrasonic cleaning or two-fluid cleaning may be performed. In the liquid cleaning, cleaning with the chemical liquid may be performed. Ultrapure water (UPW) may be used as the pure water. In the cleaning process, a front surface, a back surface, or both the front surface and the back surface of the substrate W may be cleaned. In addition, in the cleaning process, a bevel part in a peripheral edge region of the substrate W may be cleaned.

In the drying process, spin rinse drying may be performed, or IPA drying in which IPA made of steam is supplied and drying is performed may be performed. It should be noted that IPA supplied in the drying process is made of steam, whereas IPA supplied in an organic solvent supply process is made of liquid. In an aspect of providing the liquid IPA, a layer made of the liquid IPA (IPA film) may be provided on the surface of the substrate W. By providing such a layer, it is possible to effectively advance the dissolution of the foreign substance generation factor in the cleaning members 90, 95. Note that a purpose of supplying IPA made of steam is to supply IPA made of steam to a liquid surface of a solid gas-liquid interface by surface drying of the substrate W (solid) to promote drying in which generation of a defect called a water mark is suppressed by drying using an action of a Marangoni phenomenon occurring in the liquid. Therefore, it is unlikely that a layer made of the liquid IPA is formed on the substrate as in the present embodiment. In addition, it has been confirmed that when IPA made of steam is provided to liquid (rinse liquid or the like) on the surface of the substrate W, generation of foreign substances based on a foreign substance generation factor to be described later becomes apparent. Note that for example, when the liquid IPA is provided to the substrate W at the end of the cleaning process or in the drying process, IPA drying in which IPA made of steam is supplied to a liquid (rinse liquid or the like) on the surface of the substrate W and drying is performed may not be performed.

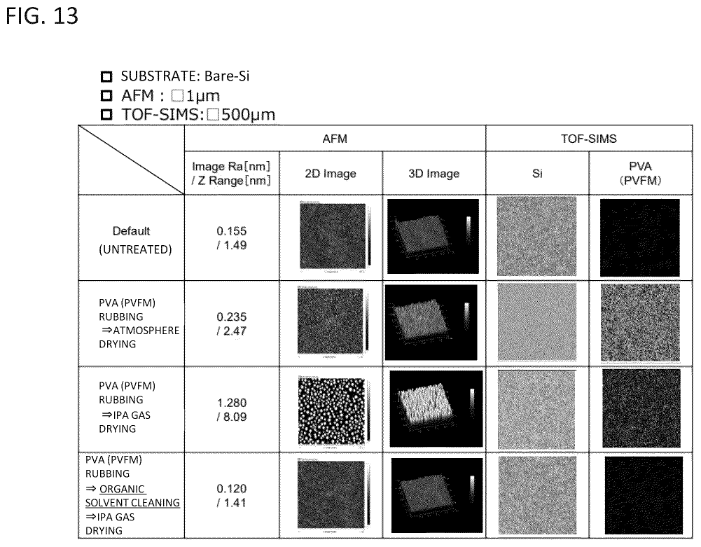

According to the inventor, it has been confirmed that by performing the contact cleaning using the roll cleaning members 90 and the pencil cleaning members 95, and then performing the IPA drying using steam, foreign substances caused by the roll cleaning members 90 and the pencil cleaning members 95 are generated and adhere to the surface of the substrate W. By providing the liquid IPA to the substrate W after the contact cleaning and before the spin rinse drying or the IPA drying (for example, by forming a liquid film made of IPA), the foreign substance generation factor can be effectively eliminated. Note that when the foreign substance generation factor caused by the cleaning members 90, 95 remains in the substrate W in a significant amount, for example, an IPA gas atmosphere acts on a resin material adhering and remaining on the surface by the drying treatment using the IPA gas, or the like, and a minute foreign substance (nm size) to be a foreign substance is generated. In a conventional method (for example, an atomic force microscope (AFM)), the foreign substance generation factor could not be confirmed, but this time, the inventor succeeded in detecting the foreign substance generation factor by using TOF-SIMS (Time-of-Flight Secondary Ion Mass Spectrometry). FIG. 13 shows results by AFM and TOF-SIMS confirmed by the inventor, and in TOF-SIMS, the results for Si as a component of a wafer and PVA (PVFM) as a component of the cleaning member are shown. The larger an adhesion amount of the foreign substance generation factor is, the brighter the result in PVA (PVFM) is, and the smaller the adhesion amount of the foreign substance generation factor is, the darker the result in PVA (PVFM) is. A first row shows a state where no processing is performed, showing a state where the foreign substance generation factor does not adhere or the adhesion amount is extremely small. A second row shows results of cleaning with a cleaning member made of PVA (PVFM) and then drying in the atmosphere. A third row shows results of cleaning with the cleaning member made of PVA (PVFM) and then drying using IPA gas. A fourth row shows results of cleaning with the cleaning member made of PVA (PVFM), then cleaning with IPA which is an organic solvent made of liquid, and then drying using IPA gas. From these results, it was confirmed that in an aspect shown in the fourth row, the brightness in PVA (PVFM) was lower than that in the second and third rows, and the foreign substance generation factor was less to an extent equivalent to the first row. In addition, the presence or absence of foreign substances can be confirmed by using AFM, but as a result of cleaning with the cleaning member made of PVA (PVFM) shown in the third row and then drying with the IPA gas, white spots were observed, and the presence of foreign substances could be confirmed. Note that in the result of TOF-SIMS for the third row, since PVA (PVFM) was dark, it was confirmed that an adhesion area of PVA (PVFM) was reduced as compared with the second row. As in the present embodiment, it is possible to provide a substrate processing apparatus such as a robust CMP apparatus that suppresses contamination by removing or reducing the foreign substance generation factor in advance, improves a defect risk of the substrate W, and improves a yield. Note that thicknesses of the fine foreign substances were several nanometers (1 nm or more), and widths were several tens of nanometers (10 nm or more).

A process of providing the liquid IPA to the substrate W may be performed in each of the plurality of cleaning processes after the physical contact with the substrate W by the cleaning members such as the roll cleaning members 90 or the pencil cleaning members 95 is performed. For example, IPA may be provided as liquid after contact cleaning by the roll cleaning members 90, and IPA may be provided as liquid after contact cleaning by the pencil cleaning members 95. Note that when an aspect is adopted in which the liquid IPA is provided to the substrate W after the contact cleaning by the roll cleaning members 90 and before the contact cleaning by the pencil cleaning members 95, it is advantageous in that a cleaning effect by the pencil cleaning members 95 can be enhanced, a life of the pencil cleaning members 95 can be extended, and cost reduction can be expected. Further, the process of providing the liquid IPA to the substrate W may be performed only once before the first cleaning process, or may be performed only once after the final cleaning process and before the drying process as shown in FIG. 4. In particular, in a case where the process of providing the liquid IPA to the substrate W is performed only once after the final cleaning process and before the drying process, the foreign substance generation factor that has not been removed in one or more cleaning processes is to be removed, and thus it is advantageous in that an amount of the required liquid IPA can be suppressed, which leads to cost reduction. However, the present invention is not limited to such an aspect, and the process of providing the liquid IPA to the substrate W may be performed before or after the cleaning step, or before or after the rinsing step. When the plurality of cleaning processes are performed, contents of the respective cleaning processes are not necessarily the same, and the plurality of cleaning processes may be performed by variously changing conditions.

By performing the cleaning by the pencil cleaning members 95 after performing the cleaning by the roll cleaning members 90, an amount of the minute foreign substances generated in the drying process can be suppressed, but it is still insufficient. Therefore, it is advantageous to provide the liquid IPA described in the present embodiment at appropriate timing. Note that by providing the liquid IPA after the cleaning by the roll cleaning members 90 and the cleaning by the pencil cleaning members 95 and before the drying process, treatment time with the liquid IPA can be reduced to improve productivity, and the amount of the liquid IPA to be used can be reduced. As a result, it is advantageous in that a CoO (Cost of Ownership) reduction effect can be enhanced. Note that when a skin layer is formed on nodules 91 of each of the roll cleaning members 90 or a side surface of each of the pencil cleaning members 95, minute foreign substances tend to be generated. Therefore, it is particularly advantageous to adopt the aspect of the present embodiment in such an aspect. Note that contamination is often generated in the substrate W due to the nodules 91 of the roll cleaning members 90, but occurrence of contamination in the substrate W can be suppressed by providing the liquid IPA to the substrate W as in the present embodiment after the cleaning using the nodules 91 of the roll cleaning members 90 is completed.

When the rinse liquid is made of pure water, the process of providing the liquid IPA may be performed before the rinse liquid (pure water) is supplied in the last cleaning process. When the rinse liquid is made of a chemical liquid other than pure water, the process of providing the liquid IPA may be performed after the rinse liquid (pure water) made of the chemical liquid is supplied in the last cleaning process. The process of providing the liquid IPA (organic solvent supply process) may be performed inside a housing in which the cleaning process is performed (inside each of the cleaning units 116, 118). However, unlike such an aspect, the process of providing the liquid IPA may be performed inside a housing in which the drying process is performed (inside the drying unit 120). In this case, the liquid IPA may be provided to the substrate W before starting the drying process such as the spin rinse drying or the IPA drying in which IPA made of steam is supplied and drying is performed.

Further, the process of providing the liquid IPA to the substrate W may be performed not in the housing in which the cleaning process is performed (inside each of the cleaning units 116, 118) or inside the housing in which the drying process is performed (inside the drying unit 120), but in a separately dedicated housing (inside a liquid IPA supply apparatus). Loading and unloading of the substrate W into and from the above housing may be performed by a conveyance mechanism such as the conveyance unit 124 or the transfer robots 126, 128. The provision of the liquid IPA to the substrate W may be performed while the substrate W is being conveyed by the conveyance mechanism.

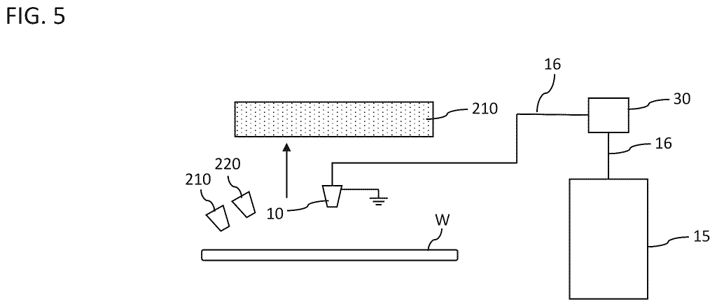

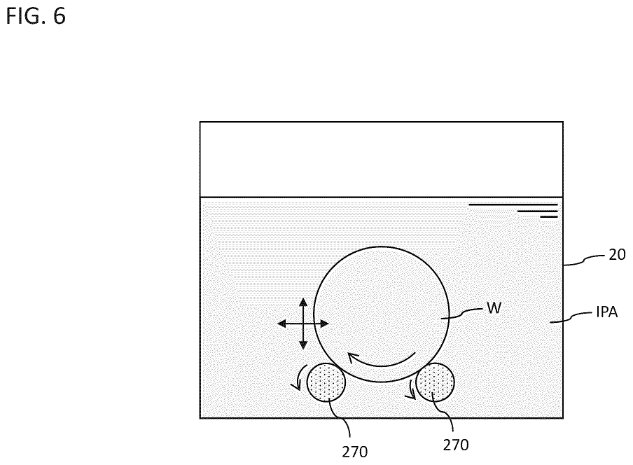

The IPA supply mechanism may be an ejection part 10 (see FIG. 5) that ejects the liquid IPA to the substrate W. As another aspect, the supply mechanism may be an immersion part 20 (see FIG. 6) for immersing the substrate W in the liquid IPA. In addition, the IPA supply mechanism may have both the ejection part 10 and the immersion part 20. When the immersion part 20 is adopted, it is advantageous in that the liquid IPA can be reliably supplied to the surface of the substrate W. The ejection part 10 may supply the liquid IPA to a central part of the substrate W, or the ejection part 10 may supply the liquid IPA to the substrate W while swinging so as to pass through a center of the substrate W in plan view. The ejection part 10 may supply the liquid IPA from an oblique direction of the substrate W. As shown in FIG. 5, the liquid IPA may be supplied to the ejection part 10 from a storage part 15 via storage pipes 16. The substrate W immersed in the immersion part 20 may be moved in the vertical and horizontal directions while being rotated by a rotation/horizontal/elevation mechanism 270 (see FIG. 6).

From the viewpoint of eliminating the foreign substance generation factor, it is preferable to heat the liquid IPA with a heating part 30 (see FIG. 5), and it is advantageous that a temperature is 30° C. or more and 60° C. or less. By adopting such a temperature region, the foreign substance generation factor can be effectively dissolved. Note that the temperature of the liquid IPA when heating is not performed by the heating part 30 is typically about 20° C. to 25° C. depending on an environment of a clean room.

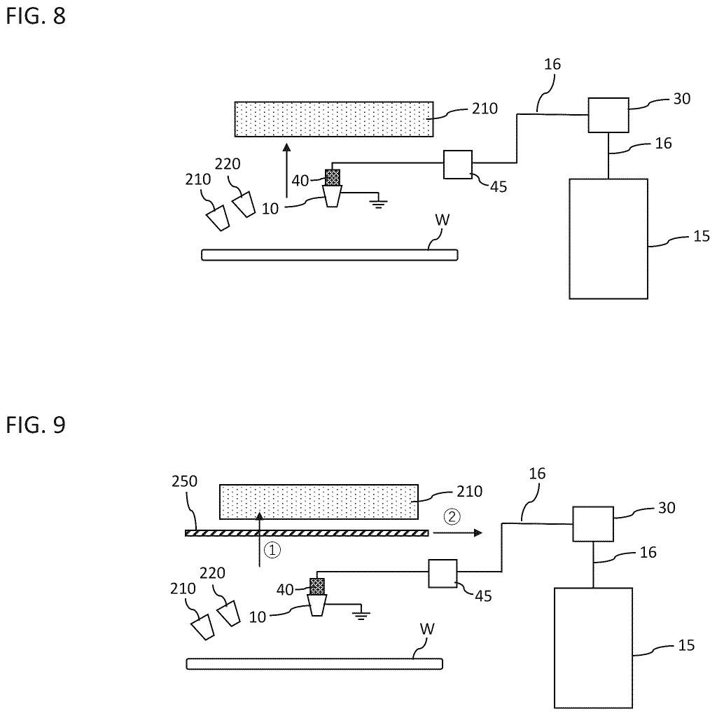

Similarly, from the viewpoint of eliminating the foreign substance generation factor, the liquid IPA may be supplied to the substrate W while applying ultrasonic waves by an ultrasonic supply part 40 (see FIG. 8), or bubbles may be contained in the liquid IPA by a bubble supply part 45 (see FIG. 8) and the liquid IPA may be supplied to the substrate W. In addition, in order to suppress oxidation, deoxygenated liquid IPA or liquid IPA in which nitrogen is dissolved after deoxygenation may be supplied to the substrate W. In addition, a liquid IPA in which argon, carbon dioxide, or the like is dissolved may be used. Further, the liquid IPA may be mixed with the cleaning chemical liquid and supplied. The liquid IPA may be supplied by a single tube formed of a tube or the like, may be supplied in a spray form, or may be supplied from a two-fluid nozzle. It is also conceivable that the liquid IPA and the chemical liquid are mixed and provided in the cleaning process.

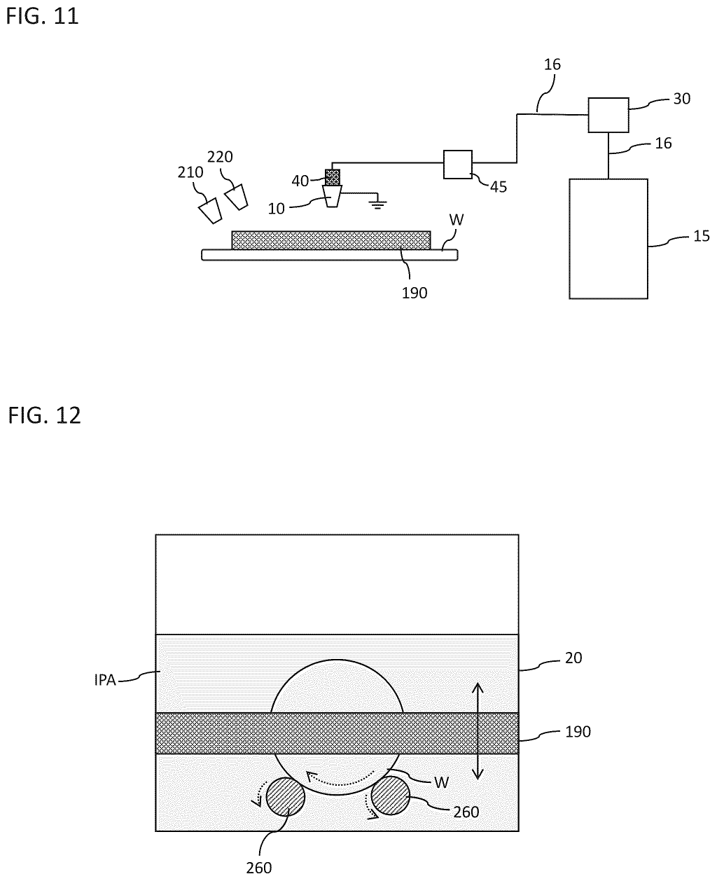

In a state where the liquid IPA is provided to the substrate W, the substrate W may be rubbed using a dedicated cleaning member 190 of a pencil type or a roll type, for example (in FIGS. 11 and 12, the roll-type dedicated cleaning member 190 is shown, but the present invention is not limited thereto, and a pencil type dedicated cleaning member may be used). Examples of the aspect in which the liquid IPA is provided to the substrate W include the aspect in which the liquid IPA is provided by the ejection part 10 and the aspect in which the liquid IPA is provided by the immersion part 20. The dedicated cleaning member 190 moves relative to the substrate W, and the dedicated cleaning member 190 comes into physical contact with the substrate W in the state where the liquid IPA is provided to the substrate W. As an example, in a state where the substrate W is rotated or stopped, the dedicated cleaning member 190 may move in plane in a state of being in contact with the surface of the substrate W. From the viewpoint of solvent resistance, for the liquid IPA, it is advantageous to use urethane, polyimide, or fluorine-based substance (PTFE or the like) as a material of the dedicated cleaning member 190. In particular, it is advantageous to use porous polyimide having a pore diameter of 1 μm or less on a member surface as the dedicated cleaning member 190. Note that, since urethane and polyimide have solvent resistance to methanol, ethanol, halogen-containing organic solvents, sulfur-containing organic solvents, nitrogen-containing organic solvents, hydrocarbon-based solvents, and the like, it is advantageous to use the dedicated cleaning member 190 made of urethane or polyimide even when these solvents are used as the organic solvent for dissolution.

In the case of adopting an aspect in which the substrate W is supported (held) so as to extend in the horizontal direction, it is advantageous in that the ejected IPA can stay on the substrate (liquid heap can be formed), and an efficiency of removal by dissolving can be enhanced.

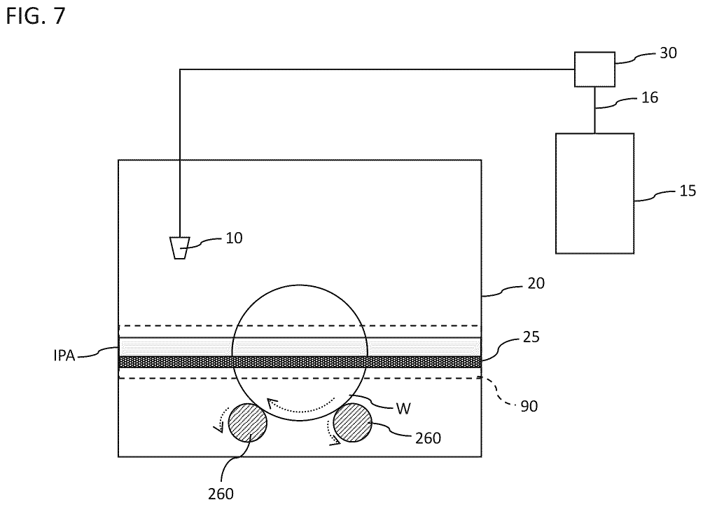

When the immersion part 20 is adopted, the configuration may be such that the entire substrate W may be immersed in IPA as shown in FIG. 6, but an extension part 25 for maintaining the substrate W in a state where the liquid IPA is in contact with the front surface and/or the back surface of the substrate W may be provided (see FIG. 7). IPA is accumulated on an upper surface of the extension part 25, and the front surface and/or the back surface of the substrate W is immersed in the IPA as the substrate W is rotated by rotation mechanisms 260. As one example, in a case where both surfaces of the substrate W are immersed in IPA, the substrate W is positioned between a pair of extension parts 25, and both the front surface and the back surface of the substrate W are immersed in IPA as the substrate W rotates. The extension part 25 may have a rod shape or a plate shape. A rotation speed of the substrate W may be low, and for example, the substrate W may be rotated at about 20 to 70 rpm.

In an aspect shown in FIG. 7, after the cleaning members such as the roll cleaning members 90 and the pencil cleaning members 95 are separated from the substrate W, the rod-shaped or plate-shaped extension part 25 described above may be brought close to the substrate W to provide only a slight gap, and then the liquid IPA may be accumulated in the extension part 25, and the substrate W may be rotated to dissolve the foreign substance generation factor adhering to the substrate W with the liquid IPA. However, the present invention is not limited to such an aspect, and although there is a risk that the roll cleaning members 90 dissolves, for example, the substrate W may be immersed in the liquid IPA by storing the liquid IPA on the roll cleaning members 90 while holding the substrate W by the roll cleaning members 90 in a state where the substrate W extends in the vertical direction. At this time, the roll cleaning members 90 may be rotating, may be stopped, or may be rotating at a lower speed than that at the time of cleaning with the chemical liquid or the rinse liquid. Note that FIG. 7 shows an aspect in which the roll cleaning members 90 are separated from the substrate W, and the roll cleaning members 90 separated from the substrate W are indicated by dotted lines. For example, the extension part 25 may enter between each of the separated roll cleaning members 90 and the substrate W from above and then approach the substrate W to be positioned at a position as shown in FIG. 7.

The substrate W may be rotated in both the case of supplying the liquid IPA from the ejection part 10 (see FIG. 5) and the case of storing the liquid IPA in the immersion part 20 (see FIGS. 6 and 7). The rotation of the substrate W may be intermittently performed, or a process of rotating the substrate W by a certain angle and then stopping the substrate W for a certain period of time may be repeatedly performed. In the configuration in which the entire substrate W is immersed in IPA, the substrate W may also be rotated. As the ejection part 10, for example, a fluorine-based resin such as a Teflon (registered trademark) material such as polytetrafluoroethylene (PTFE), polyvinylidene fluoride (PVDF), or perfluoroalkoxyalkane (PFA) can be used, but the ejection parts 10 of these fluorine-based resins containing carbon nanofibers or carbon nanotubes are preferable, and the ejection part 10 may be electrically connected to the ground. Since the ejection part 10 of a normal fluororesin material is electrified by the liquid IPA, for example, when discharge due to electrification occurs between the substrate W and the ejection part 10, there is a possibility that the ejection part 10 is destroyed, and there is a possibility that the surface of the substrate W is destroyed, leading to a decrease in yield. However, by adopting a conductive ground, it is possible to suppress the electrification of the ejection part 10 and to prevent occurrence of such inconvenience. In addition, when the ejection part 10 is electrified by the liquid IPA, there is a possibility that an electrical influence including corrosion may occur in the substrate W, but it is also advantageous in that such an influence can be prevented.

While the liquid IPA is supplied from the ejection part 10 as shown in FIG. 5, the rotation of the substrate W may be slower than that at the time of cleaning, or the rotation of the substrate W may be stopped. By adopting such an aspect, it can be expected that the foreign substance generation factor adhering to the substrate W is effectively dissolved by the liquid IPA. Note that when the rotation of the substrate W is stopped, the liquid in which the foreign substance generation factor is dissolved stagnates, and there is a concern about readhesion to the substrate W. Therefore, it is advantageous to rotate the substrate W at a constant speed. Further, when the substrate W is rotated at a high speed, the liquid IPA is discarded without sufficiently dissolving the foreign substance generation factor by the supplied IPA. Therefore, from the viewpoint of efficiently using IPA, it is advantageous to rotate the substrate W at a low speed of, for example, about 20 to 70 rpm.

When the substrate W is immersed in the liquid IPA in the immersion part 20, the rotation speed of the substrate W may be, for example, about 20 to 70 rpm.

Control related to polishing, cleaning, and drying of the substrate W including control related to rotation of the substrate W is performed by the control part 50. At this time, a signal is transmitted from the control part 50, and each of the components of the substrate cleaning apparatus is driven or stopped according to the signal.

The cleaning members such as the roll cleaning members 90 and the pencil cleaning members 95 may move to a retracted position (see FIGS. 5 and 8) when IPA is ejected from the ejection part 10. By adopting such an aspect, it is possible to prevent IPA from adhering to the cleaning members 90, 95 and dissolving the cleaning members 90, 95. In addition, a cover 250 may be provided between each of the cleaning members 90, 95 moved to the retracted position and the substrate W (see FIG. 9), or an air curtain may be provided. In this case, the cover 250 or the air curtain may be provided between the substrate W and each of the cleaning members 90, 95 after the cleaning members 90, 95 are separated from the substrate W.

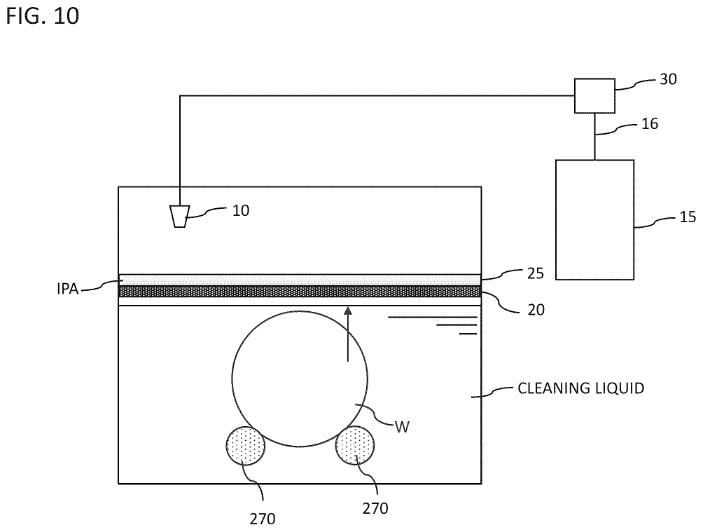

Although an aspect in which the substrate W is immersed in the rinse liquid can be adopted, in this case, the liquid IPA may be supplied at timing of taking out the substrate W from the rinse liquid (see FIG. 10). In the aspect shown in FIG. 10, the extension part 25 is provided, but the liquid IPA may be supplied at timing when the substrate W is taken out from the rinse liquid in a state where the extension part 25 is not provided. FIG. 10 shows an aspect in which the substrate W is immersed in the liquid IPA when the substrate W is taken out of the cleaning liquid by the rotation/horizontal/elevation mechanism 270. However, the substrate W may be immersed in the liquid IPA when the substrate W is pulled up from the cleaning liquid and taken out of the cleaning liquid by the conveyance mechanism, which accesses from above, instead of the rotation/horizontal/elevation mechanism 270.

The IPA gas to be used in the IPA drying may be supplied from the same storage part 15 as the liquid IPA, and a supply method (for example, a supply amount and a supply temperature) may be changed, so that the case of supplying the liquid IPA and the case of supplying gaseous IPA (IPA gas) can be appropriately changed.

When a resin such as polyvinyl alcohol (PVA) or polyvinyl formal (PVFM) is adopted as the material of the cleaning member including the roll cleaning members 90, the pencil cleaning members 95, and the like, foreign substances tend to be easily generated. Therefore, it is more effective to adopt the aspect of the present embodiment. Examples of the material of the cleaning members 90, 95 can include polyurethane, polypropylene, polyethylene, and a fluorine-based resin material in addition to PVA and PVFM described above.

The above description of the embodiments and the disclosure of the figures are merely examples for describing the invention defined in the claims, and the invention defined in the claims is not limited by the above description of the embodiments and the disclosure of the figures.

The cleaning apparatus of the present embodiment is mainly used after cleaning in a CMP apparatus which is classified into semiconductor manufacturing apparatuses, and can obtain beneficial cleaning characteristics particularly in contact physical cleaning against particle contamination on the surface of the substrate W in a manufacturing stage with the substrate W having a device structure such as a semiconductor wafer. In addition, the cleaning apparatus of the present embodiment is similarly applied to an apparatus in which particles and the like in the apparatus are concerned in classification of fine processing equipment. The cleaning apparatus according to the present embodiment can be applied, for example, to a manufacturing process of a magnetic film in a semiconductor wafer having a diameter of 300 mm or 450 mm, a flat panel, an image sensor such as a complementary metal oxide semiconductor (CMOS) or a charge coupled device (CCD), or a magnetoresistive random access memory (MRAM).

### REFERENCE SIGNS LIST

10 Ejection part
20 Immersion part
90 Roll cleaning member
95 Pencil cleaning member
200 Spindle (rotation support part)
W Substrate

1. A substrate cleaning apparatus comprising:
a cleaning member that contacts with a substrate to clean the substrate; and
a supply mechanism that provides an organic solvent for dissolution to the substrate after the substrate is cleaned by the cleaning member, the organic solvent for dissolution being to dissolve a foreign substance generation factor caused by the cleaning member.

2. The substrate cleaning apparatus according to claim 1,
wherein the organic solvent for dissolution includes a liquid isopropyl alcohol.

3. The substrate cleaning apparatus according to claim 1,
wherein the supply mechanism is an ejection part that ejects the organic solvent for dissolution to the substrate.

4. The substrate cleaning apparatus according to claim 3,
wherein the ejection part is electrically connected to a ground.

5. The substrate cleaning apparatus according to claim 1,
wherein the supply mechanism is an immersion part for immersing the substrate in the organic solvent for dissolution.

6. The substrate cleaning apparatus according to claim 1 further comprising a dedicated cleaning member that contacts with the substrate to clean the substrate, while the organic solvent for dissolution is provided to the substrate.

7. The substrate cleaning apparatus according to claim 1,
wherein the cleaning member includes a roll cleaning member and a pencil cleaning member,
wherein the supply mechanism provides the organic solvent for dissolution to the substrate, after the substrate is cleaned by the roll cleaning member and the pencil cleaning member.

8. The substrate cleaning apparatus according to claim 1 further comprising a rotation part that rotates the substrate,
wherein a rotation of the substrate is slower than the rotation of the substrate at a time of cleaning the substrate with a chemical liquid or a rinse liquid, or the rotation of the substrate is stopped, while the organic solvent for dissolution is provided by the supply mechanism.

9. The substrate cleaning apparatus according to claim 1,
wherein a temperature of the organic solvent for dissolution is 30° C. or more and 60° C. or less.

10. A substrate cleaning method comprising:
a step of bringing a cleaning member into contact with a substrate to clean the substrate; and
a step of providing, by a supply mechanism, an organic solvent for dissolution to the substrate after the substrate is cleaned by the cleaning member, the organic solvent for dissolution being to dissolve a foreign substance generation factor caused by the cleaning member.
